(19) United States
(12) Patent Application Publication
(10) Pub. No.: US 2009/0189661 A1
(43) Pub. Date: Jul. 30, 2009

(54) PULSE WIDTH MODULATION CONTROLLER AND THE CONTROLLING METHOD THEREOF

(75) Inventors: Shun Hau KAO, Hsinchu (TW); Kent HUANG, Hsinchu (TW); Hsiang Lin HUANG, Hsinchu (TW); Mao Chuan CHIEN, Hsinchu (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED ANALOG TECHNOLOGY, INC., Hsinchu (TW)

(21) Appl. No.: 12/102,314

(22) Filed: Apr. 14, 2008

(30) Foreign Application Priority Data
Jan. 29, 2008 (TW) 097103205

(51) Int. Cl. H03K 7/08

(52) U.S. Cl. 327/172

(57) ABSTRACT

A pulse width modulation controller comprises a disabling unit, a level sensor and an over current protector. These three devices are all coupled to a multi-function node for accomplishing a disable function, input level sensing, and over-current protection, respectively.

### BACKGROUND OF THE INVENTION

1. Field of the Invention

The present invention relates to power conversion, and more particularly, to a circuit and method for controlling a pulse width modulation (PWM) controller.

2. Description of the Related Art

PWM controllers are used for power regulation or power conversion. FIG. 1 shows a typical power converter 10 applying a PWM controller 18. The PWM controller 18 provides a pair of control signals UGATE and LGATE to a high side switch 12 and a low side switch 14, respectively. By controlling the conductivity of the high side switch 12 and the low side switch 14, an input power Vᵢₙ can be converted to an output power Vₒᵤₜ. The high side switch 12 couples to the low side switch 14 at a phase node 110. The output power Vₒᵤₜ drives an output stage 112, which comprises a low pass filter (shown as an LC circuit) and a load circuit R_{L}.

A PWM controller usually has at least 3 functions: disabling function, input power detecting, and over current protection. The input power detecting is for monitoring the voltage level of an input power, and setting the PWM controller to work once the input power reaches an acceptable level. The over current protection is for limiting an output current when an over current runs through the node 110. In conventional PWM controller design, these 3 functions take up additional pins, which increase the cost of packaging the PWM controller. Thus, it is important to integrate more functions using limited numbers of pins.

### SUMMARY OF THE INVENTION

The present invention proposes a PWM controller accomplishing a disable function, power sensing and over current protection with limited pins.

In one aspect of the invention, a PWM controller for driving a high side switch and a low side switch is provided. The PWM controller comprises a level sensor, a disabling unit and an over current protector. The level sensor senses a voltage level of a multi-function node and determines if the voltage level of the multi-function node exceeds a first level, wherein the multi-function node is coupled to an input power. The disabling unit disables the PWM controller when the voltage level of the multi-function node is less than a second level. The over current protector compares the voltage level of the multi-function node and the voltage level of an output node to generate a current limitation signal, wherein the output node is coupled to the high side switch and a low side switch.

In another aspect of the invention, a controlling method for driving a high side switch and a low side switch is provided. First, a voltage level of a multi-function node is obtained, wherein the voltage level of the multi-function node is a fraction of an input power. When the voltage level of the multi-function node is less than a second level, a PWM controller is disabled. The voltage level of the multi-function node is further compared with a first level for determining if the input power is ready. A voltage difference between the multi-function node and an output node is compared. A current limitation signal is generated if the voltage difference exceeds a threshold, wherein the output node is coupled to the high side switch and the low side switch.

In yet another aspect of the invention, a PWM controller for driving a pair of switches and producing an output current is provided. The PWM controller has 8 pins. A phase pin is coupled with a high side switch and a low side switch. A multi-function pin is coupled with a level sensor, a disabling unit, and an over current protector for sensing the voltage level of an input node, disabling the PWM controller by detecting the voltage level of the multi-function pin and limiting the output current by comparing the voltage difference between the phase pin and the multi-function pin, respectively.

### BRIEF DESCRIPTION OF THE DRAWINGS

The invention will be described according to the appended drawings in which:

FIG. 1 shows a conventional configuration of a PWM controller;

FIG. 2 shows a PWM controller according to one embodiment of the invention;

FIG. 3 shows an application of a PWM controller according to one embodiment of the invention; and

FIGS. 4-5 show PWM controllers according to other embodiments of the invention.

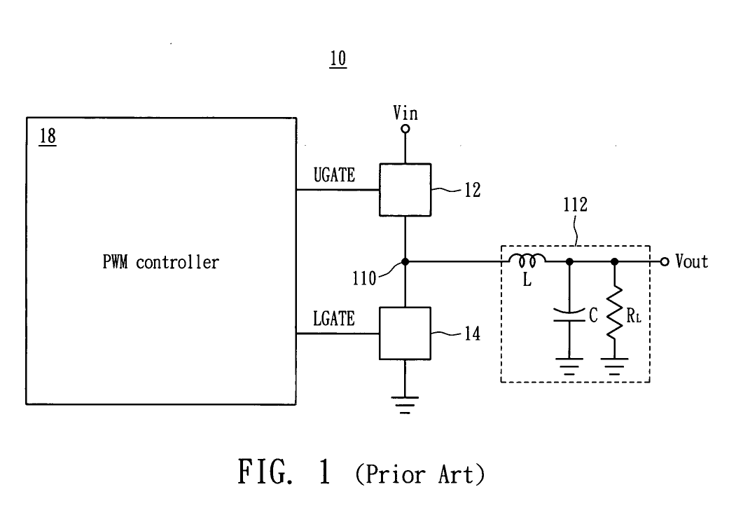

### PREFERRED EMBODIMENT OF THE PRESENT INVENTION

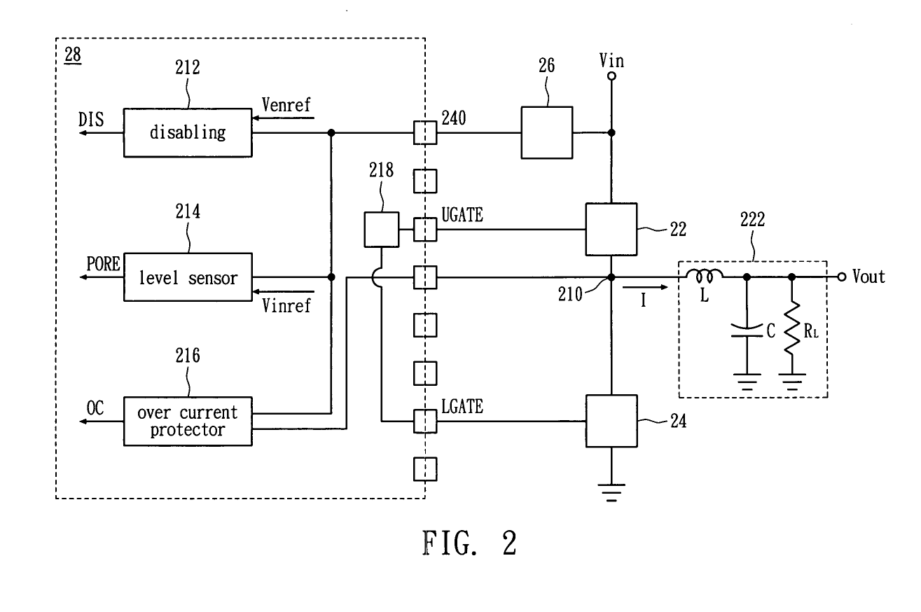

FIG. 2 shows a PWM controller 28 according to one embodiment of the invention. The PWM controller 28 comprises a disabling unit 212, a level sensor 214 and an over current protector 216. The PWM controller 28 drives a high side switch 22 and a low side switch 24, which is connecting in series between an input power Vᵢₙ and ground, and produces an output current I. A multi-function node 240 is coupled to the input power Vᵢₙ via circuit 26. The disabling unit 212 disables the PWM controller 28 when the voltage level of the multi-function node 240 is less than a second level V_{enref}. The level sensor 214 senses the voltage level of the multi-function node 240 and determines if the voltage level of the multi-function node 240 exceeds a first level V_{inref}. A signal PORE is generated when the voltage level of the multi-function node 240 exceeds the first level V_{inref} to indicate that the input power is ready. The over current protector 216 compares the voltage levels of the multi-function node 240 and the output node 210 to generate a current limitation signal OC, wherein the current limitation signal OC is used to limit the output current I.

In the embodiment of the invention, the multi-function node 240 is coupled to the input power Vᵢₙ. Thus, once the input power Vᵢₙ is ready, the signal PORE is generated, whether or not the high side switch 22 is turned on. In addition, the over current protector 216 can sense an over current once the high side switch 22 is turned on. Hence, it costs less time to respond to an over current. Last but not least, the multi-function node 240 also acts as an enable/disable node, which reduces the number of pins significantly.

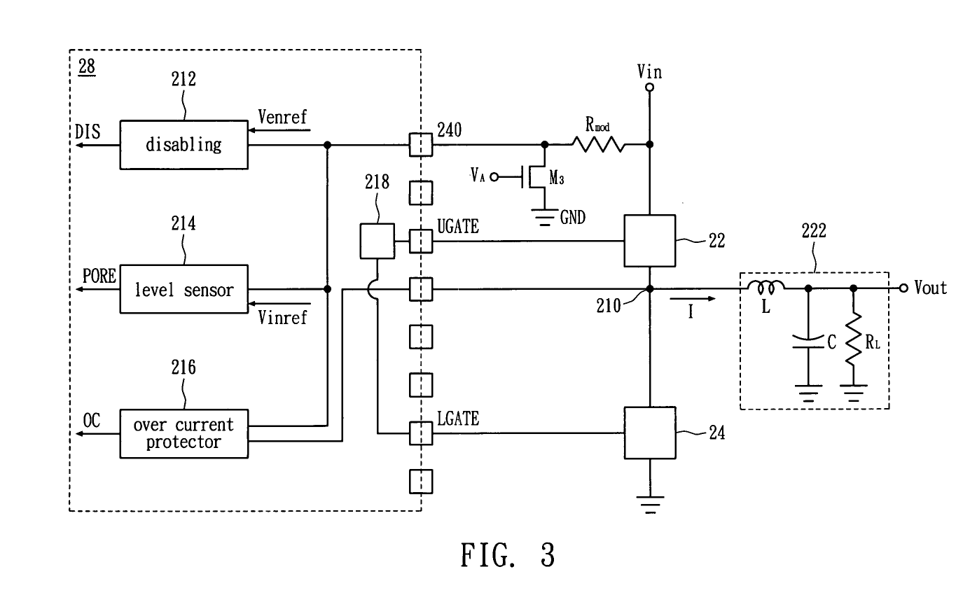

The circuit 26 can be implemented as a resistor R_{mod} and a field effect transistor (FET) M₃, as shown in FIG. 3. The FET M₃ has a drain connected to ground GND, a gate connected to bias voltage VA, and a source connected to the resistor R_{mod}. When M₃ is turned on, a current runs through the resistor R_{mod}, and the input power Vᵢₙ is adjusted to a range appropriate for succeeding units 212, 214 and 216. The PWM controller 28 outputs control signals UGATE and LGATE based on signal DIS, PORE and OC to drive the high side switch 22 and the low side switch 24. For example, once the PORE signal is generated, the high side switch 22 and the low side switch 24 are selectively turned on or off; hence the output current I is produced.

The high side switch 22 and low side switch 24 can be implemented by a transistor such as a FET, a Metal-Oxide Semiconductor FET (MOSFET) or other device for which the conductivity can be electrically controlled.

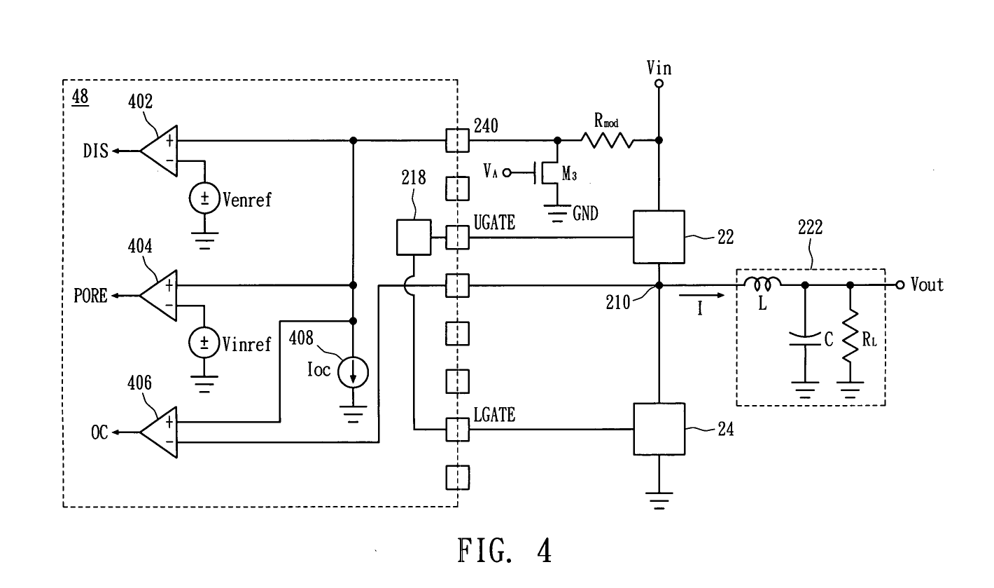

FIG. 4 shows an exemplary implementation of the disabling unit 212, the level sensor 214, and the over current protector 216. The disabling unit 212 can be implemented by a comparator 402 for comparing the voltage difference between the second level V_{enref} and the voltage level of the multi-function node 240. If the voltage level of the multi-function node 240 is less than the second level V_{enref}, the comparator 402 generates a disabling signal DIS. The level sensor 214 can be implemented by a comparator 404 for comparing the first level V_{inref} and the voltage level of the multi-function node 240. If the voltage level of the multi-function node 240 exceeds the first level V_{inref}, the comparator 404 generates a PORE signal for indicating that the input power is ready. The over current protector 216 comprises a current source 408 and a comparator 406. The current source 408 is coupled to the multi-function node 240. The comparator 406 compares the voltage level of the multi-function node 240 and the voltage level of the output node 210. If the voltage difference between the multi-function node 240 and the output node 210 exceeds zero, the over current protector generates the current limitation signal OC.

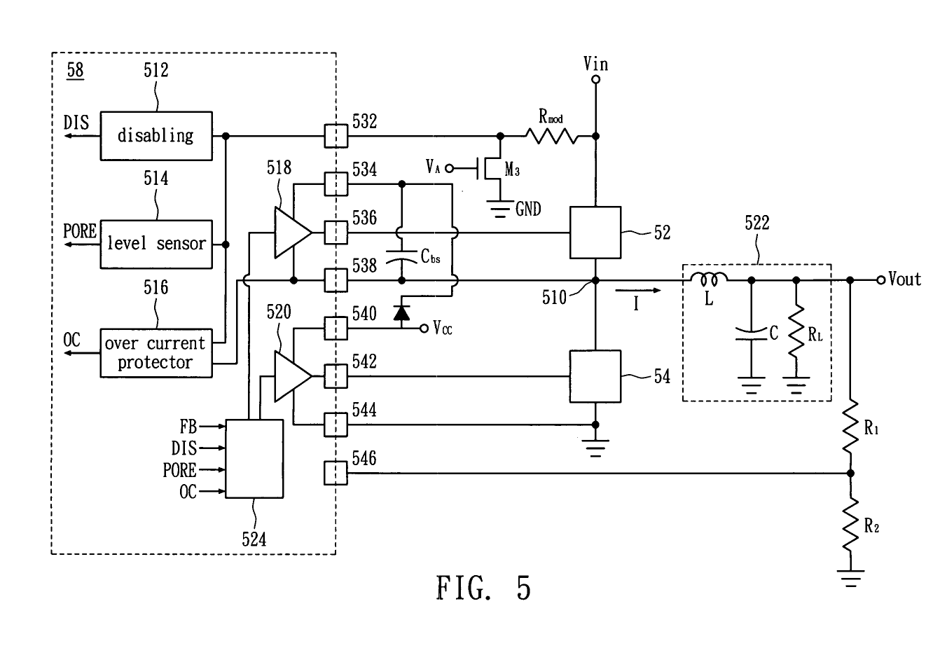

FIG. 5 shows a PWM controller 58 according to another embodiment of the invention. The PWM controller 58 has 8 pins only, which reduces the packaging cost. The 8 pins are the multi-function pin 532, boot pin 534, high side switch control pin 536, phase pin 538, power pin 540, low side switch control pin 542, ground pin 544, and feedback pin 546. It should be noted that the naming of each pin herein is for recognition only and other naming methods are also under the scope of the invention. The phase pin 538 is coupled with a high side switch 52, a low side switch 54, and an output stage 522. The output stage 522 comprises a low pass filter and a load circuit R_{L}. The feedback pin 546 is coupled to the load circuit R_{L} via a feedback network R₁ and R₂. The multi-function pin 532 is coupled with a level sensor 514, a disabling unit 512, and an over current protector 516 for sensing the voltage level of the multi-function pin 532, disabling the PWM controller 58 by detecting the voltage level of the multi-function pin 532 and limiting an output current I by comparing the voltage difference between the phase pin 538 and the multi-function pin 532, respectively. The disabling unit 512 generates a disabling signal DIS when the voltage level of the multi-function pin 532 is less than a second level. The level sensor 514 generates a PORE signal when the voltage level of the multi-function pin 532 exceeds a first level. The over current protector 516 generates a current limitation signal OC when an output current I exceeds a threshold. The power pin 540 is coupled to a supply power Vcc. The low side switch control pin 542 drives the low side switch 54 based on the voltage level of the power pin 540, the phase pin 538, the ground pin 544, the feedback pin 546, the disabling signal DIS, the PORE signal and the current limitation signal OC. The high side switch control pin 536 drives the high side switch 52 based on the voltage level of the boot pin 534, the phase pin 538, the feedback pin 546, the disabling signal DIS, the PORE signal and the current limitation signal OC. The multi-function pin 532 is further coupled to an input node Vᵢₙ via a resistor R_{mod} and coupled to the ground via a transistor M₃. A bias voltage VA connects to the gate of the transistor M₃ to control the conductivity of the transistor M₃. A diode D₁ is connected between the boot pin 534 and the power pin 540, and a capacitor C_{bs} is connected between the boot pin 534 and the phase pin 538. The above-described embodiments of the present invention are intended to be illustrative only. Numerous alternative embodiments may be devised by persons skilled in the art without departing from the scope of the following claims.

What is claimed is:

1. A Pulse Width Modulation (PWM) controller for driving a high side switch and a low side switch and producing an output current from an input power, comprising:
a level sensor for sensing a voltage level of a multi-function node and determining if the voltage level of the multi-function node exceeds a first level, wherein the multi-function node is coupled to the input power;
a disabling unit for disabling the PWM controller when the voltage level of the multi-function node is less than a second level; and
an over current protector for comparing the voltage level of the multi-function node and the voltage level of an output node for controlling the output current.

2. The PWM controller of claim 1, wherein the disabling unit comprises a comparator for comparing the second level and the voltage level of the multi-function node, and if the voltage level of the multi-function node is less than the second level, the disabling unit generates a disabling signal.

3. The PWM controller of claim 1, wherein the level sensor comprises a comparator for comparing the first level and the voltage level of the multi-function node, and if the voltage level of the multi-function node exceeds the first level, the level sensor generates a power-indicating signal.

4. The PWM controller of claim 1, wherein the over current protector further comprises:
a current source coupled to the multi-function node; and
a comparator for comparing the voltage level of the multi-function node and the voltage level of the output node, and if the voltage difference between the multi-function node and the output node exceeds zero, the over current protector generates a current limitation signal.

5. The PWM controller of claim 1, wherein the multi-function node is coupled to the input power via a resistor and is coupled to ground via a Field Effect Transistor (FET), and a gate electrode of the FET is controlled by a bias voltage.

6. The PWM controller of claim 1, wherein the high side switch and low side switch are connected in series between the input power and ground.

7. The PWM controller of claim 1, which is implemented in an 8-pin package.

8. A controlling method for driving a high side switch and a low side switch and producing an output current from an input power, comprising the steps of:
obtaining a voltage level of a multi-function node, wherein the voltage level of the multi-function node is a fraction of the input power;
disabling a PWM controller when the voltage level of the multi-function node is less than a second level;
sensing the voltage level of the multi-function node and determining if the input power exceeds a first level; and
comparing a level difference between the multi-function node and an output node for controlling an output current.

9. The method of claim 8, further comprising the step of generating a disabling signal when the voltage level of the multi-function node is less than the second level.

10. The method of claim 8, further comprising the step of generating a power-indicating signal when the voltage level of the multi-function node exceeds the first level.

11. The method of claim 8, further comprising the step of generating a current limitation signal when the voltage level of the multi-function node exceeds the voltage level of an output node, wherein the output node is coupled to the high side switch and the low side switch.

12. The method of claim 8, further comprising the steps of:
dividing the voltage level of the multi-function node by connecting a resistor and a FET in series; and
controlling a gate electrode of the FET by a bias voltage.

13. A PWM controller for driving a high side switch and a low side switch and producing an output current, the PWM controller consisting of 8 pins, wherein a phase pin is coupled with the high side switch and the low side switch, and a multi-function pin is coupled with a level sensor, a disabling unit, and an over current protector for sensing the voltage level of an input power, disabling the PWM controller by detecting the voltage level of the multi-function pin and limiting the output current by comparing the voltage difference between the phase pin and the multi-function pin, respectively.

14. The PWM controller of claim 13, wherein the disabling unit generates a disabling signal when the voltage level of the multi-function pin is less than a second level, the level sensor generates a power-indicating signal when the voltage level of the multi-function pin exceeds a first level, the over current protector generates a current limitation signal when the output current exceeds a threshold, and the other 6 pins are:
a feedback pin;
a power pin coupling to a supply power;
a ground pin for connecting to ground;
a low side switch control pin for driving the low side switch based on the voltage level of the power pin, the ground pin, the feedback pin, the disabling signal, the power-indicating signal and the current limitation signal;
a boot pin; and
a high side switch control pin driving the high side switch based on the voltage level of the boot pin, the phase pin, the feedback pin, the disabling signal, the power-indicating signal and the current limitation signal.

15. The PWM controller of claim 13, wherein the multi-function pin is coupled to the input power via a resistor and to the ground via a FET, and the gate electrode of the FET is controlled by a bias voltage.

16. The PWM controller of claim 13, wherein the boot pin is coupled to the power pin via a diode and coupled to the phase pin via a capacitor.

17. The PWM controller of claim 13, wherein the phase pin is coupled to a low pass filter and a load circuit, and the feedback pin is coupled to the load circuit via a feedback network.
